(19) United States
(12) Patent Application Publication
(10) Pub. No.: US 2024/0203773 A1
(43) Pub. Date: Jun. 20, 2024

(54) SUBSTRATE TREATING APPARATUS AND SEMICONDUCTOR MANUFACTURING EQUIPMENT INCLUDING THE SAME

(71) Applicant: SEMES CO., LTD., Cheonan-si (KR)

(72) Inventor: Jong Seok SEO, Chungcheongnam-do (KR)

(73) Assignee: SEMES CO., LTD., Cheonan-si (KR)

(21) Appl. No.: 18/528,328

(22) Filed: Dec. 4, 2023

(30) Foreign Application Priority Data
Dec. 20, 2022 (KR) 10-2022-0179760

(51) Int. Cl. H01L 21/677; H01L 21/67; H01L 21/687

(52) U.S. Cl. CPC H01L 21/67742; H01L 21/67051; H01L 21/67115; H01L 21/67225; H01L 21/68742

(57) ABSTRACT

There are provided a substrate treating apparatus for critical dimension (CD) measurement and calibration, arranged in a facility where a bake process or a development process is performed on semiconductor substrates, and semiconductor manufacturing equipment including the substrate treating apparatus. The semiconductor manufacturing equipment includes: load ports where containers loaded with a plurality of substrates are mounted; a buffer module temporarily storing the substrates; an index module transferring the substrates between the load ports and the buffer module; a plurality of process chambers treating the substrates; a transfer module transferring the substrates between the buffer module and the process chambers; and a substrate treating apparatus performing CD measurement and calibration on the substrates, wherein the substrate treating apparatus is disposed adjacent to the process chambers.

### CROSS-REFERENCE TO RELATED APPLICATION

This application claims priority from Korean Patent Application No. 10-2022-0179760 filed on Dec. 20, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a substrate treating apparatus and semiconductor manufacturing equipment including the same, and more particularly, to a substrate treating apparatus that can be utilized in a photolithography process and semiconductor manufacturing equipment including the substrate treating apparatus.

### 2. Description of the Related Art

Semiconductor manufacturing processes may be continuously carried out within semiconductor manufacturing equipment and may be classified into front-end processes and back-end processes. Here, the front-end processes refer to processes of forming circuit patterns on a wafer to complete a semiconductor chip, while the back-end processes refer to processes of evaluating the performance of a completed product obtained through the front-end processes.

The semiconductor manufacturing equipment can be installed within a semiconductor manufacturing plant called a fab. Wafers go through various processes such as deposition, photolithography, etching, ion implantation, cleaning, packaging, and inspection, sequentially moving to equipment where each process is performed to produce semiconductors.

Photolithography is a process for forming patterns on semiconductor substrates, and includes coating, exposure, and development processes. A post-exposure bake (PEB) process for heat-treating semiconductor substrates may be performed after the exposure process.

The critical dimension (CD) for semiconductor substrates may be determined after the PEB process. The CD is associated with temperature and airflow during the PEB process, but conventionally, since the airflow is fixed and only the uniformity of the temperature is optimized, there is a clear limit in miniaturizing patterns on semiconductor substrates.

Moreover, the yield essentially relies solely on the exposure apparatus.

### SUMMARY

Aspects of the present disclosure provide a substrate treating apparatus for critical dimension (CD) measurement and calibration, which is installed in equipment where bake or development processes are performed on semiconductor substrates, and semiconductor manufacturing equipment including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, semiconductor manufacturing equipment includes: load ports where containers loaded with a plurality of substrates are mounted; a buffer module temporarily storing the substrates; an index module transferring the substrates between the load ports and the buffer module; a plurality of process chambers treating the substrates; a transfer module transferring the substrates between the buffer module and the process chambers; and a substrate treating apparatus performing CD measurement and calibration on the substrates, wherein the substrate treating apparatus is disposed adjacent to the process chambers.

According to another aspect of the present disclosure, a substrate treating apparatus includes: an inspection module measuring a CD of substrates; a control module determining whether a linewidth of patterns formed on the substrates meets a reference value based on results of the measurement of the CD of the substrates; and a calibration module performing CD calibration on the substrates if the linewidth of the patterns formed on the substrates does not meet the reference value, wherein the substrate treating apparatus is disposed adjacent to a plurality of process chambers that treat the substrates, within semiconductor manufacturing equipment.

According to another aspect of the present disclosure, semiconductor manufacturing equipment includes: load ports where containers loaded with a plurality of substrates are mounted; a buffer module temporarily storing the substrates; an index module transferring the substrates between the load ports and the buffer module; a plurality of process chambers treating the substrates; a transfer module transferring the substrates between the buffer module and the process chambers; and a substrate treating apparatus performing CD measurement and calibration on the substrates, wherein the process chambers are divided and arranged on both sides of the transfer module, which is equipped with a robot for transferring the substrates, process chambers disposed on one side of the transfer module are process chambers that perform heat treatment on the substrates, process chambers disposed on the other side of the transfer module are process chambers that perform a development process on the substrates, the substrate treating apparatus is disposed adjacent to a process chamber that performs a hard bake process, among the process chambers that perform heat treatment on the substrates, the substrate treating apparatus includes an inspection module measuring CD of the substrates, a control module determining whether a linewidth of patterns formed on the substrates meets a reference value based on results of the measurement of the CD of the substrates, and a calibration module performing the CD calibration on selected areas of the substrates based on results of the determination, and the substrate treating apparatus performs the CD measurement and calibration on at least one substrate that has gone through a hard bake process, a post exposure bake (PEB) process, or an exposure process or applies heat to a substrate to be subject to the PEB process, using a laser light source.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a first exemplary schematic view illustrating the internal configuration of semiconductor manufacturing equipment including a substrate treating apparatus for critical dimension (CD) measurement and calibration;

FIG. 2 is a second exemplary schematic view illustrating the internal configuration of the semiconductor manufacturing equipment including the substrate treating apparatus for CD measurement and calibration;

FIG. 3 is a plan view illustrating the internal configuration of a substrate treating apparatus that performs a heat treatment process on a semiconductor substrate;

FIG. 4 is a cross-sectional view of the substrate treating apparatus that performs a heat treatment process on a semiconductor substrate;

FIG. 5 is a cross-sectional view illustrating the internal configuration of a substrate processing apparatus that performs a development process on a semiconductor substrate;

FIG. 6 is a first exemplary schematic view illustrating various layouts for a substrate treating apparatus for CD inspection and calibration that constitutes the semiconductor manufacturing equipment;

FIG. 7 is a second exemplary schematic view illustrating various layouts for the substrate treating apparatus for CD inspection and calibration that constitutes the semiconductor manufacturing equipment;

FIG. 8 is a third exemplary schematic view illustrating various layouts for the substrate treating apparatus for CD inspection and calibration that constitutes the semiconductor manufacturing equipment;

FIG. 9 is a first exemplary schematic view illustrating the operation timing for the substrate treating apparatus for CD inspection and calibration;

FIG. 10 is a second exemplary schematic view illustrating the operation timing for the substrate treating apparatus for CD inspection and calibration;

FIG. 11 is a third exemplary schematic view illustrating the operation timing for the substrate treating apparatus for CD inspection and calibration; and

FIG. 12 is a block diagram illustrating the internal configuration of the substrate treating apparatus for CD inspection and calibration.

### DETAILED DESCRIPTION

Embodiments of the present disclosure will hereinafter be described with reference to the attached drawings. The same reference numerals are used for the same components in the drawings, and redundant explanations of these will be omitted.

The present disclosure relates to a semiconductor treating apparatus that can be utilized in a photolithography process and semiconductor manufacturing equipment including the semiconductor treating apparatus. The substrate treating apparatus may perform critical dimension (CD) measurement and calibration on semiconductor substrates and may be provided within a facility where a bake process or a development process for semiconductor substrates is performed. Further details of the present disclosure will hereinafter be described in detail with reference to the accompanying drawings.

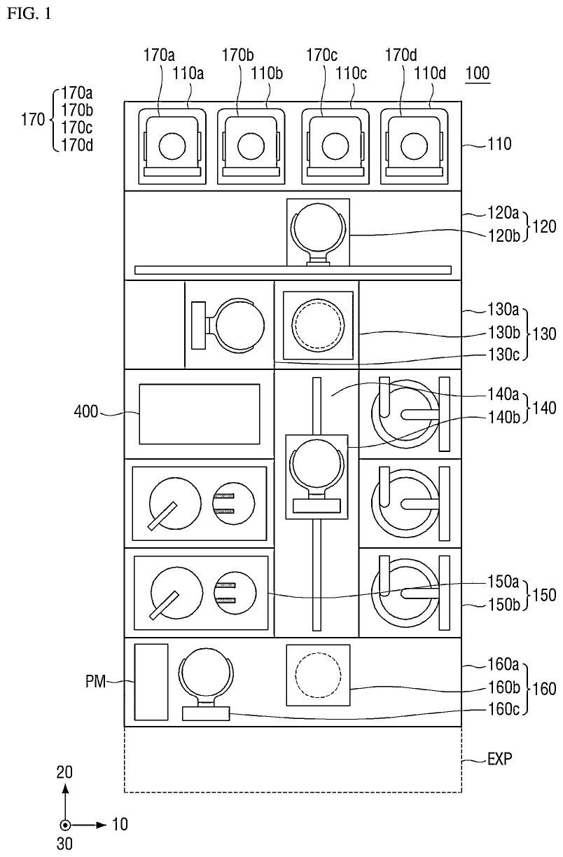

FIG. 1 is a first exemplary schematic view illustrating the internal configuration of semiconductor manufacturing equipment including a substrate treating apparatus for CD measurement and calibration. Referring to FIG. 1, semiconductor manufacturing equipment 100 may be configured to include load ports 110, an index module 120, a buffer module 130, a transfer module 140, process chambers 150, and an interface module 160.

The semiconductor manufacturing equipment 100 is a system for treating semiconductor substrates through various processes such as heat treatment and development. For this purpose, the semiconductor manufacturing equipment 100 may be implemented as a multi-chamber substrate treating system including a plurality of process chambers 150 of the same type or different types, such as a chamber for performing a heat treatment process and a chamber for performing a development process.

The load ports 110 are provided to accommodate containers 170 loaded with multiple semiconductor substrates. The containers 170 may be, for example, front opening unified pods (FOUPs).

The containers 170 may be loaded onto or unloaded from the load ports 110. Also, the semiconductor substrates stored in the containers 170 may be loaded onto or unloaded from the load ports 110.

Although not illustrated in FIG. 1, the containers 170 may be loaded onto or unloaded from the load ports 110 by a container transporting device. Specifically, the containers 170 may be loaded onto the load ports 110 by mounting the containers 170 transported by the container transporting device in the load ports 110. Similarly, the containers 170 may be unloaded from the load ports 110 by gripping the containers 170 placed on the load ports 110 with the container transporting device. The container transporting device may be, for example, an overhead hoist transporter (OHT).

The semiconductor substrates may be loaded onto or unloaded from the containers 170 placed on the load ports 110 by a substrate transfer robot 120b. Once the containers 170 are placed on the load ports 110, the substrate transfer robot 120b may approach the load ports 110 and may retrieve the semiconductor substrates from the containers 170. In this manner, the unloading of the semiconductor substrates may be performed.

Once the treatment of the semiconductor substrates is complete within the process chambers 150, the substrate transfer robot 120b may retrieve remove the semiconductor substrates from the buffer module 130 and place them back onto the containers 170. In this manner, the loading of the semiconductor substrates may be performed.

A plurality of load ports 110 may be disposed in front of the index module 120. For example, four load ports 110, i.e., first, second, third, and fourth load ports 110a, 110b, 110c, and 110d, may be disposed in front of the index module 120.

When the load ports 110 are disposed in front of the index module 120, the containers 170 mounted on the load ports 110 may accommodate different types of items. For example, when four load ports 110, i.e., the first, second, third, and fourth load ports 110a, 110b, 110c, and 110d, are provided in front of the index module 120, a first container 170a on the first load port 110a to the far left may carry a wafer-type sensor, second and third containers 170b and 170c on the second and third load ports 110b and 110c, respectively, in the middle may carry substrates (or wafers), and a fourth container 170c on the fourth load port 110d to the far right may carry a consumable part such as a focus ring or an edge ring.

However, the present embodiment is not limited to this. Alternatively, the first, second, third, and fourth containers 170a, 170b, 170c, and 170d may all carry items of the same type. Yet alternatively, some of the first, second, third, and fourth containers 170a, 170b, 170c, and 170d may carry items of the same type, and the other containers may carry items of a different type.

The index module 120 is disposed between the load ports 110 and the buffer module 130 and interfaces the transfer of the semiconductor substrates between the containers 170 on the load ports 110 and the buffer module 130. For this purpose, the index module 120 may include a substrate transfer robot 120b within a module housing 120a. At least one substrate transfer robot 120b may be provided within the module housing 120a.

Although not illustrated in FIG. 1, one or more buffer chambers may be provided within the index module 120. Untreated substrates may be temporarily stored in the buffer chambers before being transferred to the buffer module 130, and treated substrates may also be temporarily stored before being inserted into the containers 170 on the load ports 110. The buffer chambers may be provided on sidewalls that are not adjacent to either the load ports 110 or the buffer module 130, but the present disclosure is not limited thereto. Alternatively, the buffer chambers may be provided on sidewalls adjacent to the buffer module 130.

A front-end module (FEM) may be provided on a side of the buffer module 130. The FEM may include the load ports 110 and the index module 120 and may be implemented as an equipment FEM (EFEM) or a substrate FEM (SFEM).

Meanwhile, the first, second, third, and fourth load ports 110a, 110b, 110c, and 110d may be arranged in a horizontal direction (e.g., a first direction 10), but the present disclosure is not limited thereto. Alternatively, the first, second, third, and fourth load ports 110a, 110b, 110c, and 110d may be stacked in a vertical direction, in which case, the FEM may be configured as, for example, a vertically stacked EFEM.

The buffer module 130 functions as a buffer chamber between the input and output ports of the semiconductor manufacturing equipment 100. The buffer module 130 may include a buffer stage 130b, which temporarily stores the semiconductor substrates. A single buffer module 130 may be provided between the index module 120 and the transfer module 140, but the present disclosure is not limited thereto. Alternatively, a plurality of buffer modules 130 may be provided.

The buffer module 130 may be equipped with not only the buffer stage 130b but also a substrate transfer robot 130c within a module housing 130a. When a plurality of buffer stages 130b are provided, the substrate transfer robot 130c transfers the semiconductor substrates between the buffer stages 130b.

The buffer module 130 may be loaded or unloaded with the semiconductor substrates by a substrate transfer robot 140b of the transfer module 140. The buffer module 130 may also be loaded or unloaded with the semiconductor substrates by the substrate transfer robot 120b of the index module 120.

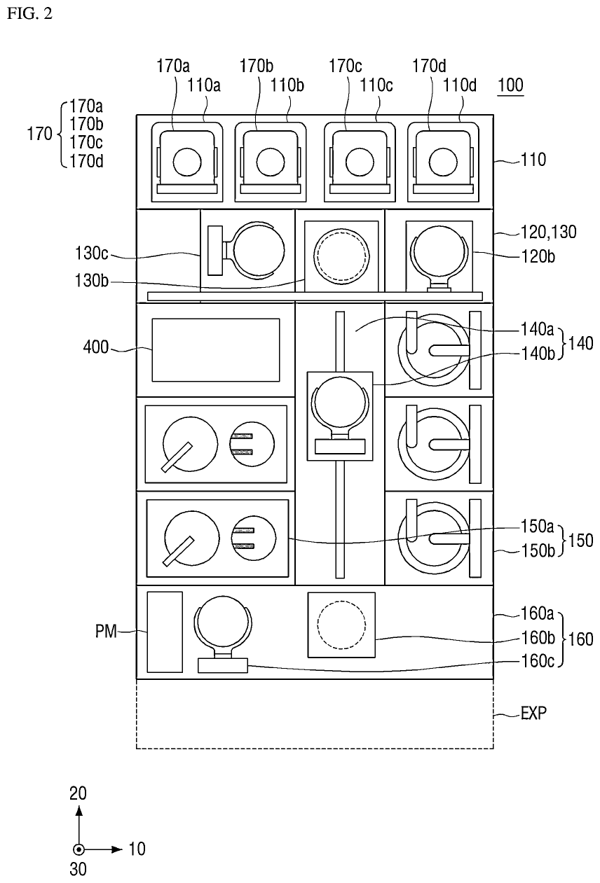

The buffer module 130 may be disposed at the rear end of the index module 120. That is, the buffer module 130 may not necessarily be disposed on the same line as the index module 120, but the present disclosure is not limited thereto. Alternatively, as illustrated in FIG. 2, the buffer module 130 may be disposed on the same line as the index module 120. In this case, the substrate transfer robot 120b of the index module 120, the substrate transfer robot 130c of the buffer module 130, and the buffer stage 130b may be disposed within a single module housing. FIG. 2 is a second exemplary schematic view illustrating the internal configuration of the semiconductor manufacturing equipment including the substrate treating apparatus for CD measurement and calibration.

Referring back to FIG. 1, the transfer module 140 interfaces the transfer of the semiconductor substrates between the buffer module 130 and the process chambers 150. To this end, the transfer module 140 may be equipped with the substrate transfer robot 140b within a module housing 140a. At least one substrate transfer robot 140b may be provided within the module housing 140a.

The substrate transfer robot 140b transfers untreated substrates from the buffer module 130 to the process chambers 150, or transfers treated substrates from the process chambers 150 to the buffer module 130. For this purpose, sides of the transfer module 140 may be connected to the buffer module 130 and the process chambers 150. Meanwhile, the substrate transfer robot 140b may be provided to be freely movable.

The process chambers 150 treats (or processes) the semiconductor substrates. A plurality of process chambers 150 may be arranged around the transfer module 140. In this case, the process chambers 150 receive the semiconductor substrates from the transfer module 140, treat the received semiconductor substrates, and then provide the treated semiconductor substrates back to the transfer module 140.

The process chambers 150 may be cylindrical or polygonal in shape. The process chambers 150 may be formed of alumite with anodized surfaces may be hermetically sealed on the inside. Meanwhile, the process chambers 150 may also be formed in various shapes other than a cylindrical or polygonal shape.

The interface module 160 transfers the semiconductor substrates. The interface module 160 may include a module housing 160a, a buffer stage 160b, and a substrate transfer robot 160c. The buffer stage 160b and the substrate transfer robot 160c are positioned within the module housing 160a. A single buffer stage 160b may be provided, but the present disclosure is not limited thereto. Alternatively, a plurality of buffer stages 160b may be provided, in which case, the buffer stages 160b may be a predetermined distance apart from one another and may be stacked on one another.

The substrate transfer robot 160c transports the semiconductor substrates between the buffer stage 160b and an exposure device EXP. The buffer stage 160b temporarily stores semiconductor substrates yet to be processed by the exposure device EXP before transferring them to the exposure device EXP, or temporarily stores semiconductor substrates that have processed by the exposure device EXP. Only the aforementioned buffers and robots may be provided in the interface module 160 without any chambers for performing particular processes on the semiconductor substrates.

Meanwhile, a purge module PM may be provided in the module housing 160a of the interface module 160, but the present disclosure is not limited thereto. Alternatively, the purge module PM may also be provided at various other locations such as where the exposure device EXP is connected at the rear end of the interface module 160 or on a side of the interface module 160.

As previously described, the buffer stage 130b may be provided in the buffer module 130, and the buffer stage 160b may be provided in the interface module 160. The buffer stage 130b may be defined as a first buffer stage or first buffer stages, and the buffer stage 160b may be defined as a second buffer stage or second buffer stages to distinguish between the buffer stages 130b and 160b.

Also, as previously explained, the substrate transfer robot 120b may be provided in the index module 120, the substrate transfer robot 130c may be provided in the buffer module 130, the substrate transfer robot 140b may be provided in the transfer module 140, and the substrate transfer robot 160c may be provided in the interface module 160. The substrate transfer robots 120b, 130c, 140b, and 160c are defined as first, second, third, and fourth transfer robots, respectively, to distinguish between the substrate transfer robots 120b, 130c, 140b, and 160c.

As illustrated in FIG. 1, the semiconductor manufacturing equipment 100 may be formed to have an in-line platform structure, as illustrated in FIG. 1. In this case, the process chambers 150 may be arranged in an in-line manner with respect to the transfer module 140, and different process chambers 150 may be arranged in series on both sides of the transfer module 140 to correspond to each other. However, the present disclosure is not limited to this. Alternatively, the semiconductor manufacturing equipment 100 may also be formed to have a cluster platform structure or a quad platform structure.

Although not explicitly illustrated in FIGS. 1 and 2, the semiconductor manufacturing equipment 100 may further include a control device. The control device controls the overall operations of the components of the semiconductor manufacturing equipment 100. For example, the control device may control substrate insertion and withdrawal performed by the substrate transfer robot 120b of the index module 120, the substrate transfer robot 130c of the buffer module 130, and the substrate transfer robot 140b of the transfer module 140 and may also control substrate processing in the processing chambers 150.

The control device may include: a process controller, which consists of a microprocessor (or a computer) that executes the control of the semiconductor manufacturing equipment 100; a user interface, which includes a keyboard for an operator to input commands and manage the semiconductor manufacturing equipment 100 and a display to visualize the operating status of the semiconductor manufacturing equipment 100; and a memory unit, which stores control programs for executing processes under the control of the process controller or programs (or processing recipes) for executing processes in the semiconductor manufacturing equipment 100 based on various data and processing conditions. The user interface and the memory unit may be connected to the process controller. The processing recipes may be stored on a storage medium within the memory unit, and the storage medium may be a hard disk, a removable disc such as a compact disc read-only memory (CD-ROM) or a digital versatile disc (DVD), or a semiconductor memory such as a flash memory.

The process chambers 150, which are provided within the semiconductor manufacturing equipment 100, i.e., substrate treating apparatuses, will hereinafter be described. As previously mentioned, the semiconductor manufacturing equipment 100 may include a plurality of process chambers 150, and these multiple process chambers 150 can be arranged in an inline fashion relative to the transfer module 140. In this case, process chambers 150 of different types may form corresponding relationships and may be arranged in rows on both sides of the transfer module 140. Process chambers 150 of one type may be substrate treating apparatuses 150a performing heat treatment on substrates, while process chambers 150 of another type may be substrate treating apparatuses 150b performing a development process on substrates.

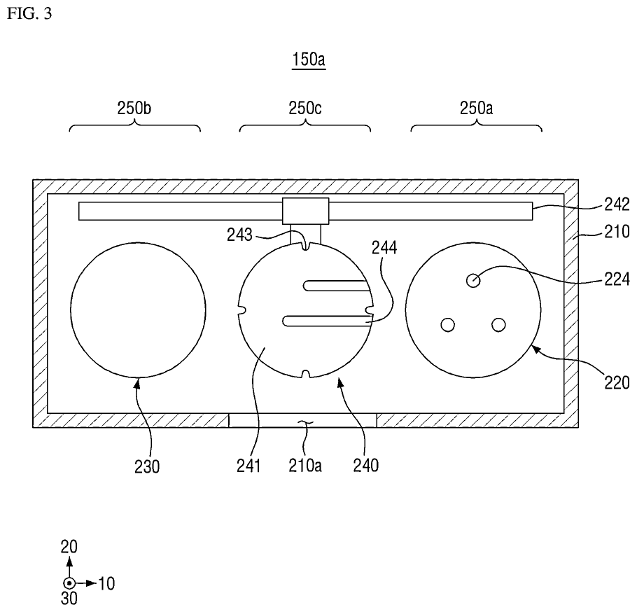

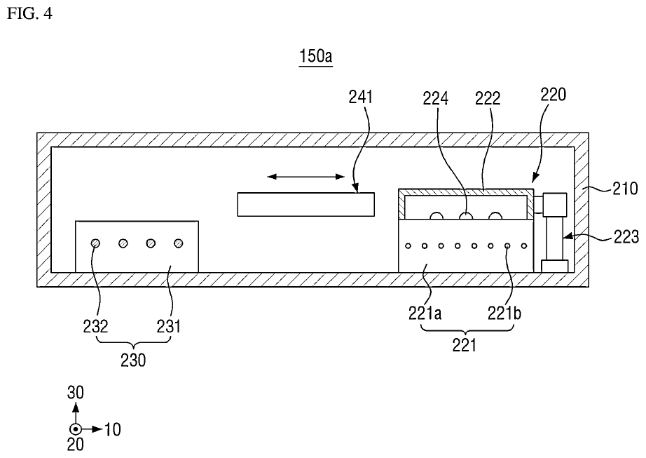

The substrate treating apparatus 150, which performs a heat treatment process, will hereinafter be described. FIG. 3 is a plan view illustrating the internal configuration of a substrate treating apparatus that performs a heat treatment process on a semiconductor substrate. FIG. 4 is a cross-sectional view of the substrate treating apparatus that performs a heat treatment process on a semiconductor substrate.

Referring to FIGS. 3 and 4, the substrate treating apparatus 150a may be configured to include a chamber housing 210, a heating unit 220, a cooling unit 230, and a transfer unit 240.

The substrate treating apparatus 150a is an apparatus for heating and cooling a substrate (e.g., a wafer). When performing a photolithography process on a substrate, the substrate treating apparatus 150a may heat and cool the substrate. The substrate treating apparatus 150a may be provided as, for example, a bake chamber performing a bake process.

The photolithography process may include a photoresist (PR) coating process, an exposure process, a development process, and a bake process. In this case, the substrate treating apparatus 150a may heat and/or cool a substrate before or after the PR coating process. Alternatively, the substrate treating apparatus 150a may heat and/or cool a substrate before or after the exposure process. Yet alternatively, the substrate treating apparatus 150a may heat and/or cool a substrate before or after the development process.

The chamber housing 210 provides space for treating a substrate. The heating unit 220, the cooling unit 230, and the transfer unit 240 may be installed within the chamber housing 210 to enable heating and cooling for a substrate.

An entry port 210a, through which a substrate enters the chamber housing 210, may be formed on a sidewall of the chamber housing 210. At least one entry port 210a may be provided in the chamber housing 210. The entry port 210a may be always kept open. Alternatively, although not illustrated in FIG. 4, the entry port 210a may be provided with a door for opening and closing the entry port 210a.

The internal space of the chamber housing 210 may be divided into three areas: a heating area 250a, a cooling area 250b, and a buffer area 250c. Here, the heating area 250a refers to the area where the heating unit 220 is located, and the cooling area 250b refers to the area where the cooling unit 230 is located. The heating area 250a may be provided with the same width as or a greater width than the heating unit 220. Similarly, the cooling area 250b may be provided with the same width as or a greater width than the cooling unit 230.

The buffer area 250c refers to the area where a transfer plate 241 of the transfer unit 240 is located. The buffer area 250c may be provided between the heating area 250a and the cooling area 250b. In this case, the buffer area 250c may prevent thermal interference between the heating unit 220 and the cooling unit 230 by keeping the heating unit 220 and the cooling unit 230 sufficiently separated. Similarly to the heating area 250a and the cooling area 250b, the buffer area 250c may be provided with the same width as or a greater width than the transfer plate 241.

When the heating unit 220, the cooling unit 230, and the transfer unit 240 are disposed on the heating area 250a, the cooling area 250b, and the buffer area 250c, respectively, within the chamber housing 210, the cooling unit 230, the transfer unit 240, and the heating unit 220 may be sequentially arranged in the first direction 10, but the present disclosure is not limited thereto. Alternatively, the heating unit 220, the transfer unit 240, and the cooling unit 230 may be sequentially arranged in the first direction 10.

The heating unit 220 heats the substrate. When the heating unit 220 heats the substrate, the heating unit 220 may supply gas to the substrate. For example, the heating unit 220 may supply a hexamethyldisilane gas, and the supply of this type of gas may enhance the adhesion of PR to the substrate.

The heating unit 220 may be configured to include a heating plate 221, a cover module 222, and a driving module 223.

The heating plate 221, which is also referred to as a hot plate, applies heat to the substrate. To this end, the heating plate 221 may include a body part 221a and heaters 221b.

The body part 221a supports the substrate when applying heat to the substrate. The body part 221a may be formed to have the same diameter as or a greater diameter than the substrate.

The body part 221a may be formed of a material with excellent heat resistance or fire resistance. For example, the body part 221a may be formed of ceramics such as aluminum oxide (Al₂O₃) or aluminum nitride (AlN).

Meanwhile, although not illustrated in FIGS. 3 and 4, the body part 221a may include a plurality of vacuum holes that are formed to penetrate in the vertical direction (e.g., the third direction 30). Here, the vacuum holes may create a vacuum pressure to secure the substrate when applying heat to the substrate.

Meanwhile, although not explicitly illustrated in FIGS. 3 and 4, the body part 221a may be divided into an upper plate and a lower plate. In this case, the substrate may be mounted on the upper plate, and the heaters 221b may be installed within the lower plate.

The heaters 221b applies heat to the substrate on the body part 221a. A plurality of heaters 221b may be installed within the body part 221a. The heaters 221b may be configured as heating resistors (for example, heating elements) through which a current is applied. However, the heaters 221b may be of any other form as long as they can effectively apply heat to the substrate on the body part 221a.

The cover module 222 is formed to cover the top of the heating plate 221 when the heating plate 221 heats the substrate. The cover module 222 may move in the vertical direction (or the third direction 30) under the control of the driving module 223 to open and close the top of the heating plate 221.

The driving module 223 is for moving the cover module 222 in the vertical direction (or the third direction 30). When the substrate is securely positioned on the top of the heating plate 221 for heat treatment, the driving module 223 may move the cover module 222 in a downward direction toward the chamber housing 210 to completely cover the top of the heating plate 221. Also, once the heat treatment of the substrate is complete, the driving module 223 may move the cover module 222 in an upward direction, thereby exposing the top of the heating plate 221 to allow the transfer unit 240 to move the substrate to the cooling unit 230.

The cooling unit 230 cools the substrate that has been heated by the heating unit 220. For this purpose, the cooling unit 230 may be configured to include a cooling plate 231 and cooling elements 232.

When high-temperature heat is applied to the substrate via the heating unit 220, warpage of the substrate may occur. The cooling unit 230 may restore the substrate to its original state by cooling the substrate down to an appropriate temperature.

The cooling elements 232 are formed within the cooling plate 231. The cooling elements 232 may be provided as flow paths through which a cooling fluid flows.

The transfer unit 240 moves the substrate to either the heating unit 220 or the cooling unit 230. For this purpose, the transfer unit 240 may have a hand coupled with a transfer plate 241 at its end and may move the transfer plate 241 along a guide rail 242 toward where the heating unit 220 or the cooling unit 230 is located.

The transfer plate 241, which is disc-shaped, may be formed to have a diameter corresponding to the substrate. The transfer plate 241 may include a plurality of notches 243, which are formed along the edge of the transfer plate 241, and a plurality of guide grooves 244, which are on the top surface of the transfer plate 241 and have a slit shape.

The guide grooves 244 may be formed to extend from the end of the transfer plate 241 toward the center of the transfer plate 241. The guide grooves 244 may be spaced apart in the same direction (or the first direction 10). The guide grooves 244 may prevent interference between the transfer plate 241 and lift pins 224 when the substrate is transferred between the transfer plate 241 and the heating unit 220.

The substrate is heated when it is directly placed on the heating plate 221 and is cooled when the transfer plate 241 where the substrate is placed comes into contact with the cooling plate 231. To facilitate efficient heat transfer between the cooling plate 231 and the substrate, the transfer plate 241 may be formed of a material with excellent thermal conductivity (e.g., a metal).

Meanwhile, although not illustrated in FIGS. 3 and 4, the transfer unit 240 may receive the substrate from an externally installed substrate transfer robot through the inlet 210a of the chamber housing 210.

The lift pins 224 have a free-fall structure and serve the role of lifting up or down the substrate on the heating plate 221. After receiving the substrate from the transfer unit 240, the lift pins 224 may descend to secure the substrate on the heating plate 221 for a baking process. Once the baking process is complete, the lift pins 224 may ascend to transfer the substrate back to the transfer unit 240. The lift pins 224 may be formed to penetrate the heating plate 221 in the vertical direction (or the third direction 30).

The lift pins 224, like the body part 221a, may be formed of a material with excellent heat resistance. In this case, the lift pins 224 may be formed of the same metal as the body part 221a, but alternatively, the lift pins 224 and the body part 221a may also be formed of different metals.

For example, the lift pins 224 may be driven using a linear motor (LM) guide system and may be controlled by a plurality of cylinders connected to the LM guide system. The LM guide system has the advantage of being able to cope with high temperatures and vibrations.

Meanwhile, a plurality of lift pins 224 may be installed on the heating plate 221 to stably support the substrate when lifting up the substrate from the heating plate 221. For example, as illustrated in FIGS. 3 and 4, three lift pins 224 may be installed.

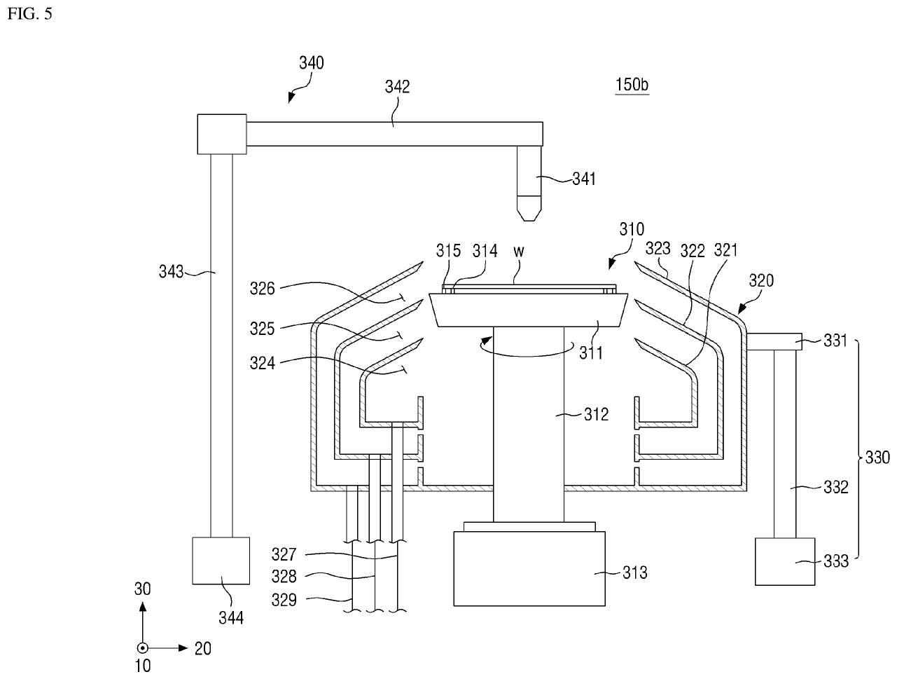

The substrate treating apparatus 150b will hereinafter be described in further detail. FIG. 5 is a cross-sectional view illustrating the internal configuration of a substrate processing apparatus that performs a development process on a semiconductor substrate.

The substrate treating apparatus 150b is an apparatus that treats a semiconductor substrate W using chemical solutions. The substrate treating apparatus 150b may use the chemical solutions to remove photoresist from the semiconductor substrate W. The substrate treating apparatus 150b may be implemented as a cleaning process chamber that cleans the semiconductor substrate W using the chemical solutions.

Here, the chemical solutions may be liquid substances (e.g., organic solvents) or gaseous substances. The chemical solutions may have high volatility, generate fumes, or have high viscosity and are thus residue-prone. The chemical solutions may be selected from among materials that include isopropyl alcohol (IPA) components, sulfuric acid components (e.g., sulfuric peroxide mixture (SPM) containing sulfuric acid and hydrogen peroxide), ammonia components (e.g., SC-1 (i.e., H2O2+NH4OH)), hydrofluoric acid components (e.g., diluted hydrogen fluoride (DHF)), and phosphoric acid components. Chemical solutions for treating the semiconductor substrate W may be defined as substrate treating solutions.

When the substrate treating apparatus 150b is applied for a cleaning process, the substrate treating apparatus 150b may rotate the semiconductor substrate W using a spin head and may provide a chemical solution onto the surface of the semiconductor substrate W using a nozzle. As illustrated in FIG. 5, when configured as a liquid treating chamber, the substrate treating apparatus 150b may include a substrate support unit 310, a treating solution recovery unit 320, a lifting unit 330, and a spraying unit 340.

The substrate support unit 310 is a module that supports the semiconductor substrate W. The substrate support unit 310 may rotate the semiconductor substrate W in a direction perpendicular to the third direction 30, for example, in the first direction 10 or a second direction 20, during the treatment of the semiconductor substrate W. The substrate support unit 310 may be disposed within the solution recovery unit 320 to recover substrate treating solutions used during the treatment of the semiconductor substrate W.

The substrate support unit 310 may be configured to include a spin head 311, a rotary shaft 312, a rotary driving module 313, support pins 314, and guide pins 315.

The spin head 311 rotates along the direction of rotation of the rotary shaft 312, which is perpendicular to the third direction 30. The spin head 311 may be provided to have the same shape as the semiconductor substrate W, but the present disclosure is not limited thereto. The spin head 311 may also be provided to have a different shape from the semiconductor substrate W.

The rotary shaft 312 generates a rotational force using energy provided by the rotary driving module 313. The rotary shaft 312 may be coupled to both the rotary driving module 313 and the spin head 311 and may deliver the rotational force from the rotary driving module 313 to the spin head 311. The spin head 311 rotates along with the rotary shaft 312, in which case, the semiconductor substrate W attached to the spin head 311 may also rotate with the spin head 311.

The support pins 314 and the guide pins 315 fix the semiconductor substrate W on the spin head 311. The support pins 314 support the bottom surface of the semiconductor substrate W on the spin head 311, while the guide pins 315 support the side surfaces of the semiconductor substrate W. Multiple support pins 314 and multiple guide pins 315 may be installed on the spin head 311.

The support pins 314 may be disposed with a circular ring shape as a whole. As a result, the support pins 314 can support the bottom surface of the semiconductor substrate W at a predetermined distance from the top of the spin head 311.

The guide pins 315, which are chucking pins, may support the semiconductor substrate W in place and prevent the semiconductor substrate W from being detached from its original position when the spin head 311 rotates.

The treating solution recovery unit 320 recovers the substrate treating solutions used to treat the semiconductor substrate W. The treating solution recovery unit 320 may be installed around the substrate support unit 310, providing space for performing a treating operation on the semiconductor substrate W.

After the semiconductor substrate W is attached and fixed on the substrate support unit 310 and starts rotating under the control of the substrate support unit 310, the spraying unit 340 may inject substrate treating solutions onto the semiconductor substrate W under the control of a control device. Then, due to the centrifugal force generated by the rotational force of the substrate support unit 310, the substrate treating solutions ejected onto the semiconductor substrate W may be dispersed in the directions where the treating solution recovery unit 320 is located. In this case, the treating solution recovery unit 320 may recover the substrate treating solutions when the substrate treating solutions flow into its interior through inflow ports (i.e., a first opening 324 of a first recovery tank 321, a second opening 325 of a second recovery tank 322, and a third opening 326 of a third recovery tank 323).

The treating solution recovery unit 320 may be configured include multiple recovery tanks. For example, the treating solution recovery unit 320 may include three recovery tanks. In this case, the substrate treating solution used to treat the semiconductor substrate W may be separated and recovered, enabling the recycling of the substrate treating solutions.

The treating solution recovery unit 320 may include three recovery tanks, i.e., the first, second, and third recovery tanks 321, 322, and 323. The first, second, and third recovery tanks 321, 322, and 323 may be implemented, for example, as bowls.

The first, second, and third recovery tanks 321, 322, and 323 may recover different substrate treating solutions. For example, the first recovery tank 321 may recover a rinse liquid (e.g., deionized (DI) water), the second recovery tank 322 may recover a first chemical solution, and the third recovery tank 323 may recover a second chemical solution.

The first, second, and third recovery tanks 321, 322, and 323 may be connected to recovery lines 327, 328, and 329 extending in a downward direction (or the third direction 30) from the bottom surfaces of the first, second, and third recovery tanks 321, 322, and 323. First, second, and third treating solutions recovered through the first, second, and third recovery tanks 321, 322, and 323, respectively, may be processed and made reusable through a treating solution regeneration system (not illustrated).

The first, second, and third recovery tanks 321, 322, and 323 may be provided in a circular ring shape surrounding the substrate support unit 310. The size of the first, second, and third recovery tanks 321, 322, and 323 may gradually increase from the first recovery tank 321 to the third recovery tank 323 (e.g., in the second direction 20). When the distance between the first and second recovery tanks 321 and 322 is defined as a first gap and the distance between the second and third recovery tanks 322 and 323 is defined as a second gap, the first gap may be the same as the second gap, but the present disclosure is not limited thereto. Alternatively, the first gap may differ from the second gap. In other words, the first gap may be larger or smaller than the second gap.

The lifting unit 330 is for rectilinearly moving the treating solution recovery unit 320 in the vertical direction (or the third direction 30). The lifting unit 330 may adjust the relative height of the treating solution recovery unit 320 with respect to the substrate support unit 310 (or the semiconductor substrate W).

The lifting unit 330 may be configured to include a bracket 331, a first support shaft 332, and a first driving module 333.

The bracket 331 is fixed to the outer wall of the treating solution recovery unit 320. The bracket 331 may be coupled with the first supporting axis 332, which moves in the vertical direction under the control of the first driving module 333.

When the semiconductor substrate W is attached to the substrate support unit 310, the substrate support unit 310 may be positioned above the treating solution recovery unit 320. Similarly, when the semiconductor substrate W is detached from the substrate support unit 310, the substrate support unit 310 may also be positioned above the treating solution recovery unit 320. In such cases, the lifting unit 330 may lower the treating solution recovery unit 320.

When the semiconductor substrate W is being treated, the substrate treating solutions ejected onto the semiconductor substrate W may be recovered into one of the first, second, and third recovery tanks 321, 322, and 323, depending on their types. Even in this case, the lifting unit 330 may lift or lower the treating solution recovery unit 320 to each desired position. For example, if the first treating solution is used, the lifting unit 330 may lift the treating solution recovery unit 320 to a height corresponding to the first opening 324 of the first recovery tank 321.

Meanwhile, the lifting unit 330 may adjust the relative height of the treating solution recovery unit 320 with respect to the substrate support unit 310 (or the semiconductor substrate W) by rectilinearly moving the substrate support unit 310 in the vertical direction.

However, the present disclosure is not limited to this. Alternatively, the lifting unit 330 may adjust the relative height of the treating solution recovery unit 320 with respect to the substrate support unit 310 (or the semiconductor substrate W) by rectilinearly moving both the substrate support unit 310 and the treating solution recovery unit 320 at the same time in the vertical direction.

The spraying unit 340 is a module that supplies substrate treating solutions onto the semiconductor substrate W during the treatment of the semiconductor substrate W. At least one spraying unit 340 may be installed within the substrate treating apparatus 150b. When a plurality of spraying units 340 are installed within the substrate treating apparatus 150b, the spraying units 340 may inject different substrate treating solutions onto the semiconductor substrate W.

The spraying unit 340 may be configured to include a nozzle structure 341, a nozzle support module 342, a second support shaft 343, and a second driving module 344.

The nozzle structure 341 is installed at one end of the nozzle support module 342. The nozzle structure 341 may be moved to a processing position or a standby position by the second driving module 344.

Here, the processing position refers to a region above the semiconductor substrate W, while the standby position refers to regions other than the processing position. To eject a substrate treating solution onto the semiconductor substrate W, the nozzle structure 341 may be moved to the processing position. Then, after ejecting the substrate treating solution onto the semiconductor substrate W, the nozzle structure 341 may move away from the processing position to the standby position.

The nozzle support module 342 supports the nozzle structure 341. The nozzle support module 342 may extend in a direction corresponding to the length direction of the spin head 311. In other words, the length direction of the nozzle support module 342 may be provided along the second direction 20.

The nozzle support module 342 may be coupled to the second support shaft 343, which extends in a vertical direction with respect to its length direction. The second support shaft 343 may extend in a direction corresponding to the height direction of the spin head 311. In other words, the length direction of the second support shaft 343 may be provided along the third direction 30.

The second driving module 344 is a module that rotates and elevates the second support shaft 343 and the nozzle support module 342, which is linked with the second support shaft 343. As a result, the nozzle structure 341 may be moved to the processing position or the standby position.

Although not explicitly illustrated in FIG. 5, the substrate treating apparatus 150b may further include a substrate treating solution supply module. The substrate treating solution supply module provides a substrate treating solution into the substrate treating apparatus 150b.

To this end, the substrate treating solution supply module may be connected to the spraying unit 340 and may operate under the control of the control device.

The semiconductor manufacturing equipment 100, particularly, the substrate treating apparatuses 150a and 150b, which are provided within the semiconductor manufacturing equipment 100 and perform a heat treatment process and a development process, respectively, on the semiconductor substrate W, have been described so far with reference to FIGS. 1 and 2. The semiconductor manufacturing equipment may be provided as spinner equipment.

Generally, only the substrate treating apparatuses 150a and 150b are provided within the spinner equipment, and apparatuses for CD inspection and CD calibration are not provided within the spinner equipment. Thus, CD inspection may be performed on the semiconductor substrate W only after a photolithography process, such as a development process or and a hard bake process, is completed. However, this imposes limitations on both pattern miniaturization and yield enhancement.

On the contrary, according to some embodiments of the present disclosure, a substrate treating apparatus capable of conducting CD inspection and calibration on the semiconductor substrate W may be installed within the semiconductor manufacturing equipment 100, along with the substrate treating apparatuses 150a and 150b, which perform heat treatment and development, respectively. This will hereinafter be further explained.

For clarity and convenience, the substrate treating apparatus 150a, which performing a heat treatment process on the semiconductor substrate W, the substrate treating apparatus 150b, which performs a development process on the semiconductor substrate W, and a substrate treating apparatus 400, which performs CD inspection and calibration on the semiconductor substrate W, will hereinafter be referred to as the first substrate treating apparatus 150a, the second substrate treating apparatus 150b, and a third substrate treating apparatus 400, respectively.

As previously mentioned, the first and second substrate treating apparatus 150a and 150b may be arranged in a row on both sides of the transfer module 140. In this case, the third substrate treating apparatus 400 may be disposed in the same space as the first substrate treating apparatus 150a. The third substrate treating apparatus 400 may be disposed on the outside of a plurality of first substrate treating apparatuses 150a that are aligned in a row, but the present disclosure is not limited thereto. Alternatively, the third substrate treating apparatus 400 may be disposed between two different first substrate treating apparatuses 150a.

When the third substrate treating apparatus 400 is disposed in the same space as a plurality of first substrate treating apparatuses 150a, the first substrate treating apparatuses 150a may be arranged near the third substrate treating apparatus 400. One of the first substrate treating apparatuses 150a may be a process chamber for performing a PEB process, and another one of the first substrate treating apparatuses 150a may be a process chamber for performing a hard bake process. At least one process chamber for performing a PEB process and at least one process chamber for performing a hard bake process may be provided, and the third substrate treating apparatus 400 may be disposed near the process chamber for performing a hard bake process.

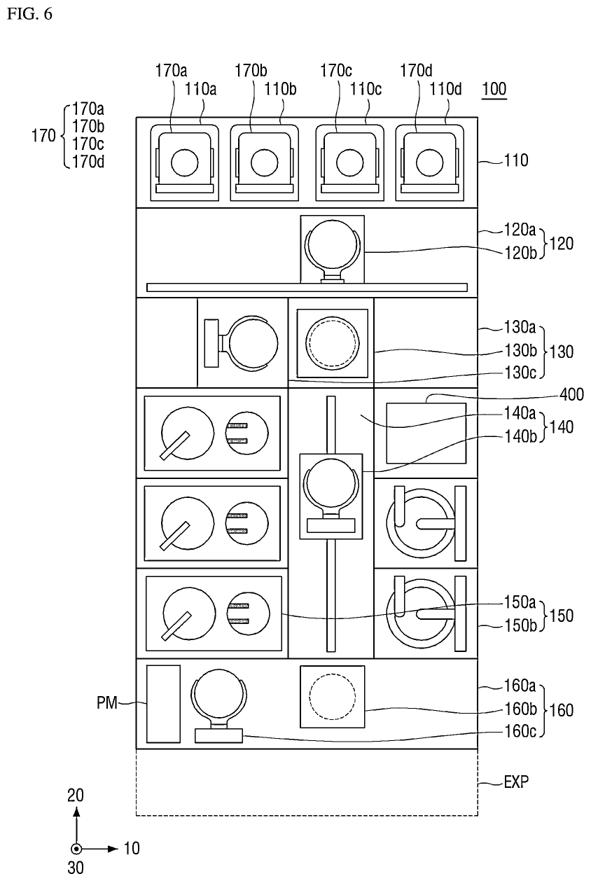

Referring to FIG. 6, the third substrate treating apparatus 400 may also be disposed in the same space as second substrate treating apparatuses 150b. In this case, the third substrate treating apparatus 400 may be disposed on the outside of a plurality of second substrate treating apparatuses 150b that are arranged in a row, but the present disclosure is not limited thereto. Alternatively, the third substrate treating apparatus 400 may be disposed between two different second substrate treating apparatuses 150b. FIG. 6 is a first exemplary schematic view illustrating various layouts for a substrate treating apparatus for CD inspection and calibration that constitutes the semiconductor manufacturing equipment.

FIGS. 1, 2, and 6 illustrate an example where the third substrate treating apparatus 400 is disposed in the space where the process chambers 150 are installed, but the present disclosure is not limited thereto. Alternatively, the third substrate treating apparatus 400 may be provided within the buffer module 130 or within the interface module 160.

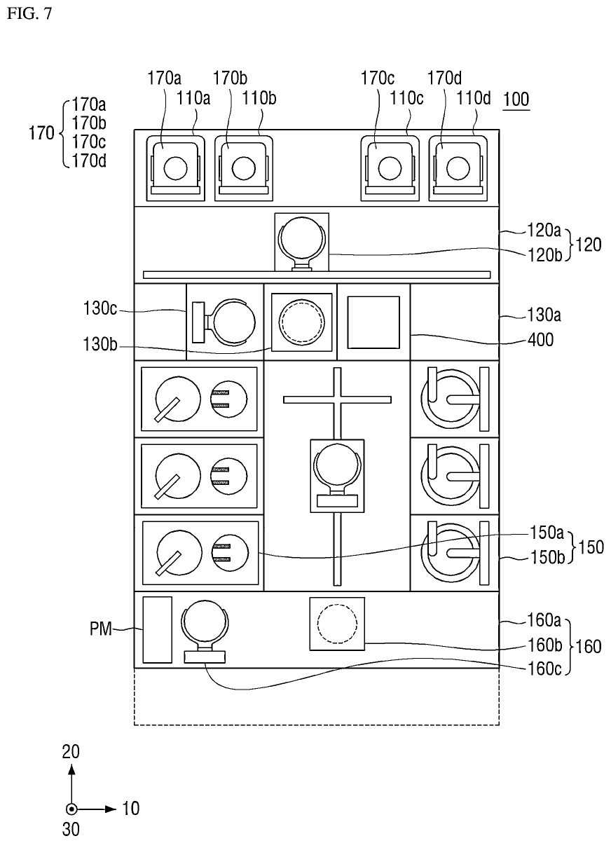

When the third substrate treating apparatus 400 is provided within the buffer module 130, the substrate transfer robot 140b may be movable not only in the second direction 20, but also in the first direction 10, for the transfer of the semiconductor substrate W. The third substrate treating apparatus 400 may be arranged in parallel to the buffer stage 130b and may be disposed adjacent to the transfer module 140, within the buffer module 130. FIG. 7 is a second exemplary schematic view illustrating various layouts for the substrate treating apparatus for CD inspection and calibration that constitutes the semiconductor manufacturing equipment.

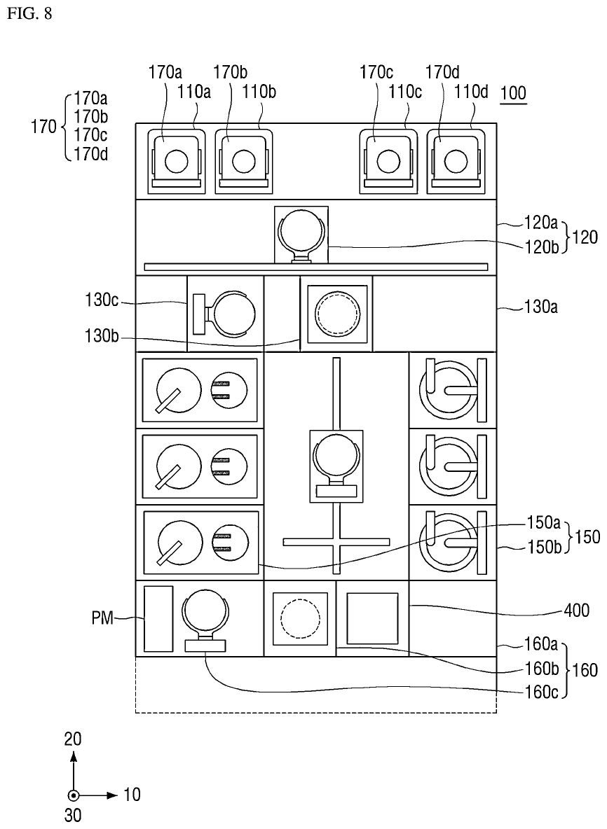

Similarly, when the third substrate treating apparatus 400 is provided within the interface module 160, the substrate transfer robot 140b may be movable not only in the second direction 20, but also in the first direction 10, for the transfer of the semiconductor substrate W. The third substrate treating apparatus 400 may be arranged in parallel to the buffer stage 160b and may be disposed adjacent to the transfer module 140, within the interface module 160. FIG. 8 is a third exemplary schematic view illustrating various layouts for the substrate treating apparatus for CD inspection and calibration that constitutes the semiconductor manufacturing equipment.

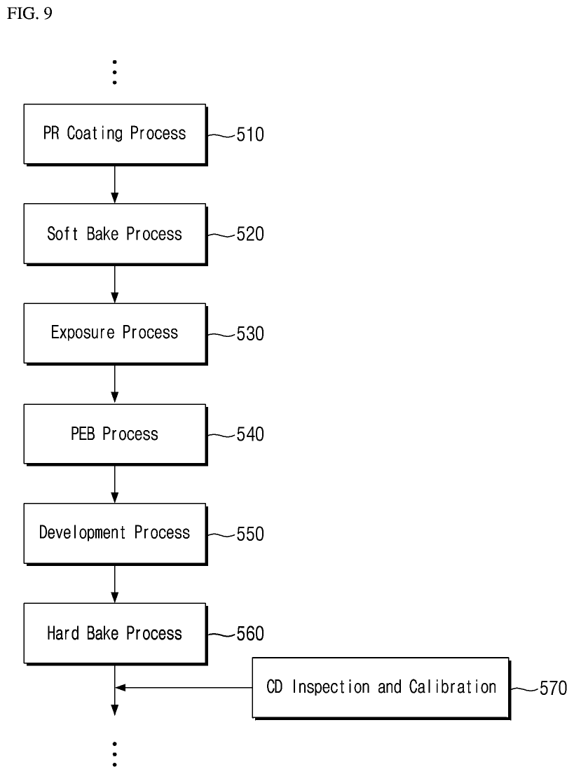

Referring to FIG. 9, a photolithography process for the semiconductor substrate W may be completed by sequentially performing a PR coating process (510), a soft bake process (520), an exposure process (530), a PEB process (540), a development process (550), and a hard bake process (560).

According to the aforementioned layout of the third substrate treating apparatus 400 within the semiconductor manufacturing equipment 100, the third substrate treating apparatus 400 may perform CD inspection and calibration (570) on the semiconductor substrate W after the hard bake process (560) is completed. For this purpose, the third substrate treating apparatus 400 may be disposed near the process chamber for performing the hard bake process. FIG. 9 is a first exemplary schematic view illustrating the operation timing for the substrate treating apparatus for CD inspection and calibration.

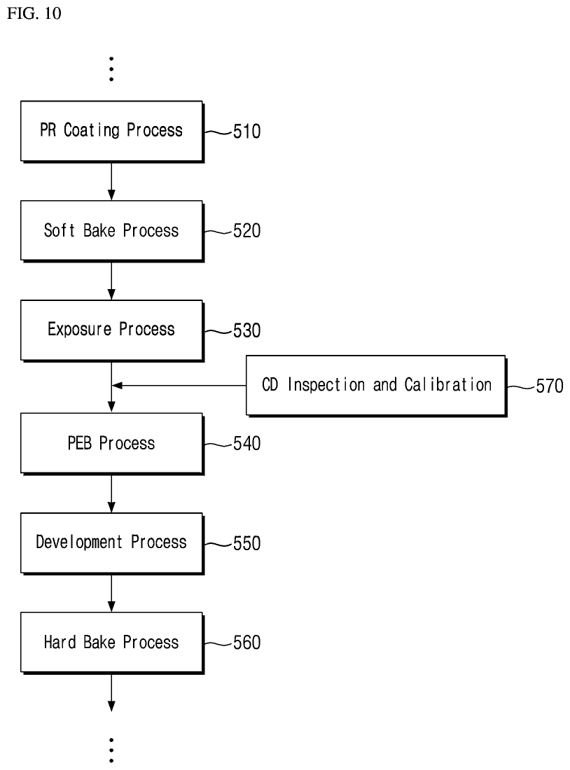

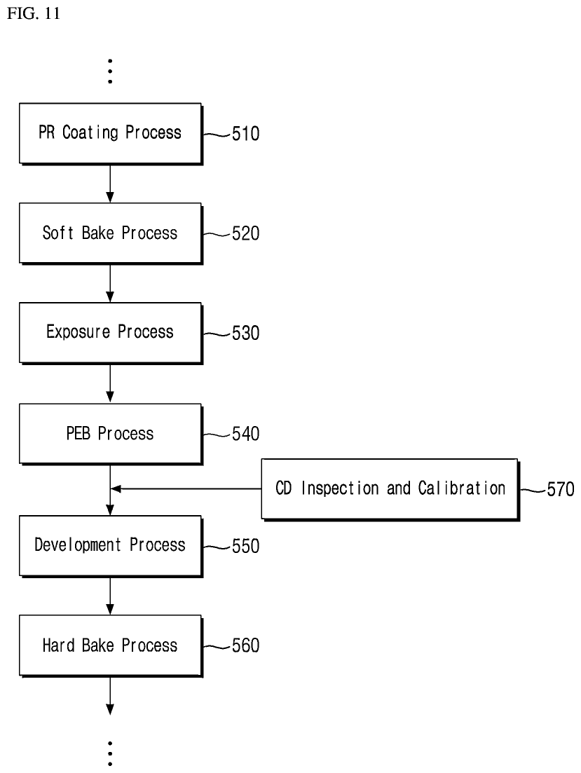

However, the present disclosure is not limited to this. Alternatively, referring to FIG. 10, the third substrate treating apparatus 400 may perform CD inspection and calibration (570) on the semiconductor substrate W between the exposure process (530) and the PEB process (540). Alternatively, referring to FIG. 11, the third substrate treating apparatus 400 may perform CD inspection and calibration (570) on the semiconductor substrate W between the PEB process (540) and the development process (550). FIG. 10 is a second exemplary schematic view illustrating the operation timing for the substrate treating apparatus for CD inspection and calibration. FIG. 11 is a third exemplary schematic view illustrating the operation timing for the substrate treating apparatus for CD inspection and calibration.

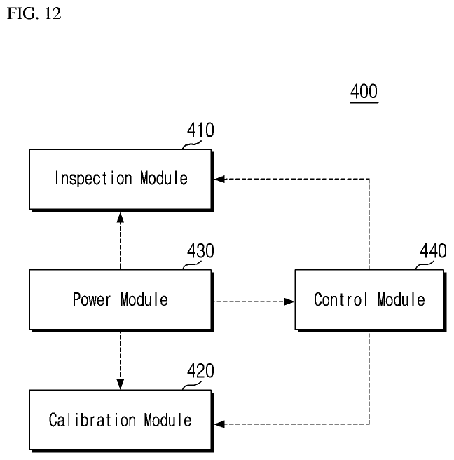

Referring to FIG. 12, the third substrate treating apparatus 400 may include an inspection module 410, a calibration module 420, a power module 430, and a control module 440. FIG. 12 is a block diagram illustrating the internal configuration of the substrate treating apparatus for CD inspection and calibration.

The inspection module 410 performs CD inspection on the semiconductor substrate W. The CD inspection may be performed by measuring the linewidth of a PR pattern formed on the semiconductor substrate W.

The control module 440 determines whether the size of the PR pattern meets a reference value based on the results of the CD inspection from the inspection module 410. The control module 440 may determine whether the linewidth of the PR pattern is greater or smaller than a target value by comparing the size of the PR pattern with the reference value.

The calibration module 420 corrects part on the semiconductor substrate W where the PR pattern is determined by the control module 440 as not meeting the reference value (i.e., an area where the linewidth of the PR pattern is determined to be greater or smaller than the target value). The calibration module 420 may correct such part or area of the semiconductor substrate W by applying heat. The calibration module 420 may use a laser light source to apply heat to such part or area of the semiconductor substrate W.

The power module 430 may provide power to the inspection module 410, the calibration module 420, and the control module 440, enabling the inspection module 410, the calibration module 420, and the control module 440 to operate.

Meanwhile, the third substrate treating apparatus 400 may also treat the semiconductor substrate W that has undergone an exposure process, on behalf of the first substrate treating apparatus 150a, which performs a PEB process. The third substrate treating apparatus 400 may perform CD inspection on the semiconductor substrate W that has undergone an exposure process and may perform CD calibration on the semiconductor substrate W based on the results of PR pattern linewidth determination.

The present disclosure relates to CD calibration technology using laser after a PEB process and to an equipment configuration that includes a CD measurement device and a CD calibration device using a laser light source within spinner equipment. By using the laser light source instead of a heater for a PEB process, the production of semiconductor substrates W can be increased, and the internal structure of the spinner equipment can be simplified.

After the PEB process, the CD of semiconductor substrates W is measured in equipment specialized for CD measurement, and the yield is identified. The present disclosure may include both the CD measurement device and the CD calibration device equipped with the laser light source within the spinner equipment.

Based on CD result data, each localized area can be effectively calibrated using the laser light source, thereby improving the yield. Additionally, selective CD measurement is enabled for semiconductor substrates W released from an exposure apparatus, and can proceed using the laser light source, instead of the PEB process.

An aggressive method to increase the yield of semiconductor substrates W may involve configuring the CD inspection device and the CD calibration device using the laser light source within the spinner equipment. Since CD calibration is performed based on CD measurement result data, localized adjustment is enabled.

According to some embodiments of the present disclosure, after a hard bake process, the third substrate treating apparatus 400 may perform CD measurement and may perform CD calibration only in areas that require CD calibration using the laser light source. Depending on conditions, CD calibration may be performed after the PEB process, and the third substrate treating apparatus 400 may be installed in an area where the bake process is performed, and may then be transferred to a robot, thereby completing CD calibration before the release of the semiconductor substrates W.

The features of the present disclosure are as follows.

First, a CD inspection device and a laser light source capable of calibration can be included within spinner equipment.

Second, the CD inspection device and the laser light source can utilize the space next to a process chamber that performs a hard bake process.

Third, multiple laser light sources can be used to improve production rate, and the scanning method is varied.

Fourth, a PEB process can be replaced simply by using the laser light source(s), instead of using a heater.

The present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. Semiconductor manufacturing equipment comprising:
load ports where containers loaded with a plurality of substrates are mounted;
a buffer module temporarily storing the substrates;
an index module transferring the substrates between the load ports and the buffer module;
a plurality of process chambers treating the substrates;
a transfer module transferring the substrates between the buffer module and the process chambers; and
a substrate treating apparatus performing critical dimension (CD) measurement and calibration on the substrates,
wherein the substrate treating apparatus is disposed adjacent to the process chambers.

2. The semiconductor manufacturing equipment of claim 1, wherein
the process chambers are divided and arranged on both sides of the transfer module, and
the substrate treating apparatus is disposed on one of the two sides of the transfer module.

3. The semiconductor manufacturing equipment of claim 2, wherein
process chambers disposed on one side of the transfer module are process chambers that perform heat treatment on the substrates, and
process chambers disposed on the other side of the transfer module are process chambers that perform a development process on the substrates.

4. The semiconductor manufacturing equipment of claim 3, wherein
the substrate treating apparatus is disposed on the same side as the process chambers that perform heat treatment.

5. The semiconductor manufacturing equipment of claim 3, wherein the substrate treating apparatus is disposed adjacent to a process chamber that performs a hard bake process.

6. The semiconductor manufacturing equipment of claim 1, wherein the substrate treating apparatus includes an inspection module measuring a CD of the substrates, a control module determining whether a linewidth of patterns formed on the substrates meets a reference value based on results of the measurement of the CD of the substrates, and a calibration module performing the CD calibration on the substrates if the linewidth of the patterns formed on the substrates does not meet the reference value.

7. The semiconductor manufacturing equipment of claim 6, wherein the control module divides each of the substrates into a plurality of areas and determines whether the linewidth of the patterns meets the reference value for each of the plurality of areas.

8. The semiconductor manufacturing equipment of claim 7, wherein the calibration module performs the CD calibration on selected areas of the substrates based on results of the determination performed by the control module.

9. The semiconductor manufacturing equipment of claim 6, wherein the calibration module performs the CD calibration on the substrates using a laser light source.

10. The semiconductor manufacturing equipment of claim 9, wherein the laser light source applies heat to selected areas of the substrates.

11. The semiconductor manufacturing equipment of claim 1, wherein
the process chambers include a process chamber that performs a hard bake process, and
the substrate treating apparatus performs the CD measurement and calibration on substrates that have undergone the hard bake process.

12. The semiconductor manufacturing equipment of claim 1, wherein
the process chambers include a process chamber that performs a post exposure bake (PEB) process, and
the substrate treating apparatus performs the CD measurement and calibration on substrates that have undergone the PEB process.

13. The semiconductor manufacturing equipment of claim 1, wherein the substrate treating apparatus performs the CD measurement and calibration on substrates that have undergone a PEB process.

14. The semiconductor manufacturing equipment of claim 13, further comprising:
an interface module temporarily storing substrates that have undergone an exposure process,
wherein the transfer module releases the substrates that have undergone the exposure process from the interface module.

15. The semiconductor manufacturing equipment of claim 1, wherein the substrate treating apparatus applies heat to substrates to be subject to a PEB process, using a laser light source.

16. The semiconductor manufacturing equipment of claim 15, wherein the process chambers do not include a process chamber that performs a PEB process.

17. A substrate treating apparatus comprising:
an inspection module measuring a critical dimension (CD) of substrates;
a control module determining whether a linewidth of patterns formed on the substrates meets a reference value based on results of the measurement of the CD of the substrates; and
a calibration module performing CD calibration on the substrates if the linewidth of the patterns formed on the substrates does not meet the reference value,
wherein the substrate treating apparatus is disposed adjacent to a plurality of process chambers that treat the substrates, within semiconductor manufacturing equipment.

18. The substrate treating apparatus of claim 17, wherein
the process chambers are divided and arranged on both sides of a transfer module equipped with a robot for transferring the substrates,
process chambers disposed on one side of the transfer module are process chambers that perform heat treatment on the substrates,
process chambers disposed on the other side of the transfer module are process chambers that perform a development process on the substrates, and
the substrate treating apparatus is disposed adjacent to a process chamber that performs a hard bake process, among the process chambers that perform heat treatment on the substrates.

19. The substrate treating apparatus of claim 17, wherein the substrate treating apparatus performs the CD measurement and calibration on at least one substrate that has gone through a hard bake process, a post exposure bake (PEB) process, or an exposure process or applies heat to a substrate to be subject to the PEB process, using a laser light source.

20. Semiconductor manufacturing equipment comprising:
load ports where containers loaded with a plurality of substrates are mounted;
a buffer module temporarily storing the substrates;
an index module transferring the substrates between the load ports and the buffer module;
a plurality of process chambers treating the substrates;
a transfer module transferring the substrates between the buffer module and the process chambers; and
a substrate treating apparatus performing critical dimension (CD) measurement and calibration on the substrates,
wherein
the process chambers are divided and arranged on both sides of the transfer module, which is equipped with a robot for transferring the substrates,
process chambers disposed on one side of the transfer module are process chambers that perform heat treatment on the substrates,
process chambers disposed on the other side of the transfer module are process chambers that perform a development process on the substrates,
the substrate treating apparatus is disposed adjacent to a process chamber that performs a hard bake process, among the process chambers that perform heat treatment on the substrates,
the substrate treating apparatus includes an inspection module measuring CD of the substrates, a control module determining whether a linewidth of patterns formed on the substrates meets a reference value based on results of the measurement of the CD of the substrates, and a calibration module performing the CD calibration on selected areas of the substrates based on results of the determination, and
the substrate treating apparatus performs the CD measurement and calibration on at least one substrate that has gone through a hard bake process, a post exposure bake (PEB) process, or an exposure process or applies heat to a substrate to be subject to the PEB process, using a laser light source.
